(19) United States
(12) Patent Application Publication
(10) Pub. No.: US 2019/0096836 A1
(43) Pub. Date: Mar. 28, 2019

(54) BUMP STRUCTURE, SEMICONDUCTOR PACKAGE INCLUDING THE BUMP STRUCTURE, AND METHOD OF FORMING THE BUMP STRUCTURE

(71) Applicant: SAMSUNG ELECTRONICS CO. , LTD., SUWON-SI (KR)

(72) Inventor: BO-IN NOH, Suwon-si (KR)

(21) Appl. No.: 15/937,586

(22) Filed: Mar. 27, 2018

(30) Foreign Application Priority Data
Sep. 28, 2017 (KR) 10-2017-0126083

(51) Int. Cl. H01L 23/00

(52) U.S. Cl. CPC H01L 24/11; H01L 24/16; H01L 2224/0508; H01L 2224/11825; H01L 2224/0401

(57) ABSTRACT

A bump structure includes an under bump metal (UBM) layer, a pillar bump and a capping layer. The UBM layer is disposed on a pad of a semiconductor chip. The pillar bump is disposed on the UBM layer. The capping layer is disposed on the UBM layer and surrounds an outer surface of the pillar bump. The capping layer has a height of about 0.5 times to 0.7 times a height of the pillar bump as measured from the UBM layer where an upper portion of the pillar bump is exposed. The capping layer suppresses stresses applied to a metal wiring in the semiconductor chip while attaching the semiconductor chip to a package substrate and maintain an adhesion force between the pillar bump and the package substrate.

### CROSS-RELATED APPLICATION

This application claims priority under 35 USC § 119 from, and the benefit of, Korean Patent Application No. 2017-0126083, filed on Sep. 28, 2017 in the Korean Intellectual Property Office (KIPO), the contents of which are herein incorporated by reference in their entirety.

### BACKGROUND

### 1. Technical Field

Exemplary embodiments are directed to a bump structure, a semiconductor package that includes the bump structure, and a method of forming the bump structure. More particularly, exemplary embodiments are directed to a bump structure that can electrically connect a semiconductor chip with a package substrate in a flip chip package, a semiconductor package that includes the bump structure, and a method of forming the bump structure.

### 2. Discussion of the Related Art

In a flip chip package, pads of a semiconductor package are electrically connected with a package substrate via bumps. To decrease a size of the flip chip package, a gap between the bumps is narrowed. Thus, a bridge can be generated between the adjacent bumps.

According to related arts, to prevent the generation of the bridge, a metal pillar is formed on the pad of the semiconductor chip. The bump is formed on the metal pillar. However, because the bump on the metal pillar can become attached to the package substrate, the metal pillar can apply stress to metal wiring in the semiconductor chip.

To prevent stress from being applied to the metal wiring, a pillar bump is formed on the pad of the semiconductor chip. The pillar bump is surrounded by a capping layer. When the capping layer has a height substantially the same as that of the pillar bump, an adhesion force between the pillar bump and the package substrate is weakened. Thus, the height of the capping layer should be slightly higher than the height of the pillar bump so that an upper portion of the pillar bump oriented toward the package substrate can be exposed. The capping layer is formed on a whole surface of the pillar bump by a plating process. Portions of the capping layer on an upper surface and an outer side upper surface of the pillar bump may be removed to expose the outer side upper surface of the pillar bump by an etching process. The etching process may not provide the capping layer with a height for suppressing stresses applied to a metal wiring in a semiconductor chip and for maintaining an adhesion force between the pillar bump and a package substrate. However, in forming the capping layer, it is challenging to control the height of the capping layer to prevent the adhesion force between the pillar bump and the package substrate from being weakened.

### SUMMARY

Exemplary embodiments can provide a bump structure of a semiconductor package that includes a capping layer that has an accurate height that can maintain an adhesion force between a pillar bump and a package substrate.

Exemplary embodiments can also provide a semiconductor package that includes the above-mentioned bump structure.

Exemplary embodiments still also provide a method of forming the above-mentioned bump structure.

According to exemplary embodiments, there is provided a bump structure of a semiconductor package. The bump structure includes an under bump metal (UBM) layer, a pillar bump and a capping layer. The UBM layer is disposed on a pad of a semiconductor chip. The pillar bump is disposed on the UBM layer. The capping layer is disposed on the UBM layer and surrounds an outer surface of the pillar bump. The capping layer has a height of about 0.5 times to 0.7 times a height of the pillar bump as measured from the UBM layer, and an upper portion of the pillar bump is exposed.

According to exemplary embodiments, there is provided a semiconductor package. The semiconductor package includes a package substrate, a semiconductor chip and a bump structure. The semiconductor chip is disposed arranged over the package substrate. The bump structure includes an under bump metal (UBM) layer, a pillar bump and a capping layer. The UBM layer is disposed on a pad of the semiconductor chip. The pillar bump is disposed on the UBM layer. The capping layer is disposed on the UBM layer and surrounds an outer surface of the pillar bump. The capping layer has a height of about 0.5 times to 0.7 times a height of the pillar bump as measured from the UBM layer and exposes an upper portion of the pillar bump oriented toward the package substrate.

According to exemplary embodiments, there is provided a method of forming a bump structure of a semiconductor package. A method of forming the bump structure of the semiconductor package includes forming a UBM layer on a pad of a semiconductor chip, forming the pillar bump on the UBM layer, forming a photoresist pattern having an opening on the UBM layer to expose an outer surface of the pillar bump and a portion of the UBM layer through the opening, and forming a capping layer the opening of the photoresist pattern.

According to exemplary embodiments, a capping layer with a height of about 0.5 times to 0.7 times the height of the pillar bump can suppress stresses applied to a metal wiring in the semiconductor chip while attaching the semiconductor chip to a package substrate and to maintain an adhesion force between the pillar bump and the package substrate. In particular, the capping layer is formed in an opening of the photoresist pattern around the pillar bump by a plating process so that the capping layer may have the height within the above-mentioned range.

### BRIEF DESCRIPTION OF THE DRAWINGS

FIG. 1 is a cross-sectional view of a bump structure in accordance with exemplary embodiments.

FIG. 2 is a cross-sectional view of a semiconductor package that includes a bump structure in FIG. 1 in accordance with exemplary embodiments.

FIG. 3 is an enlarged cross-sectional view of a portion III in FIG. 2.

FIG. 4 is a cross-sectional view of a semiconductor package that includes a bump structure in FIG. 1 in accordance with exemplary embodiments.

FIG. 5 is an enlarged cross-sectional view of a portion IV in FIG. 4.

FIGS. 6 to 16 are cross-sectional views that illustrate a method of forming a bump structure in FIG. 1.

### DETAILED DESCRIPTION OF EXEMPLARY EMBODIMENTS

Hereinafter, exemplary embodiments will be explained in detail with reference to the accompanying drawings.

Bump Structure

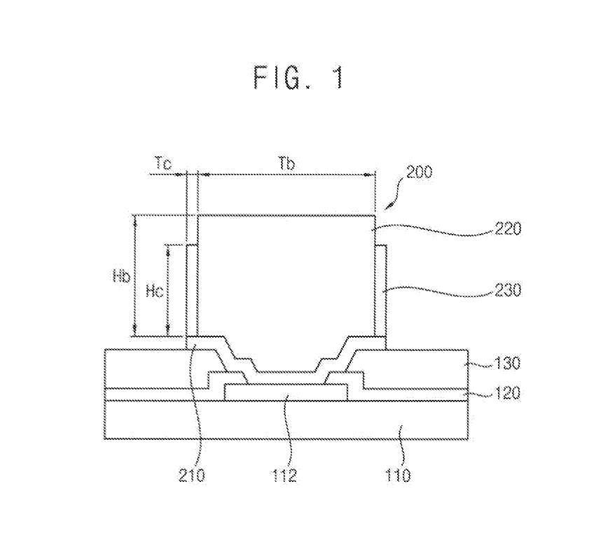

FIG. 1 is a cross-sectional view of a bump structure in accordance with exemplary embodiments.

Referring to FIG. 1, a bump structure 200 according to an exemplary embodiment is disposed on a pad 112 of a semiconductor package 110. The bump structure 200 is electrically connected with the semiconductor chip 110. The pad 112 is disposed on an upper surface of the semiconductor chip 110. The bump structure 200 can electrically connect the pad 112 of the semiconductor chip 110 with a pad of a package substrate. A passivation layer 120 is formed on the upper surface of the semiconductor chip 110. The passivation layer 120 has an opening that exposes the pad 112. An insulating pattern 130 is formed on the passivation layer 120. The insulating pattern 130 has an opening that exposes the pad 112.

According to an exemplary embodiment, the bump structure 200 includes an under bump metal (UBM) layer 210, a pillar bump 220 and a capping layer 230. The UBM layer 210 is disposed on the pad 112 of the semiconductor chip 110. The UBM layer 210 extends onto an upper surface of the insulating pattern 130.

According to an exemplary embodiment, the pillar bump 220 is disposed on an upper surface of the UBM layer 210. The pillar bump 220 is electrically connected with the pad 112 of the semiconductor chip 110 through the UBM layer 210. The pillar bump 220 can be electrically connected to the pad of the package substrate or a pad of another semiconductor chip.

According to an exemplary embodiment, the pillar bump 220 is not formed on an edge portion of the upper surface of the UBM layer 210. Thus, the edge portion of the upper surface of the UBM layer 210 is upwardly exposed. In exemplary embodiments, the pillar bump 220 includes solder. In particular, the pillar bump 220 may include tin or a tin alloy. Examples of a tin alloy include Sn—Bi, Sn—Ag, Sn—Cu, Sn—Ag—Cu, etc.

In exemplary embodiments, a height of the pillar bump 220 is measured from the UBM layer 210. Further, the pillar bump 220 has a width Tb.

According to an exemplary embodiment, the capping layer 230 is formed on the edge portion of the upper surface of the UBM layer 210 to surround the pillar bump 220. The capping layer 230 extends vertically upward from the UBM layer 210 in a direction substantially perpendicular to a plane of the pad 112 and makes contact with an outer surface of the pillar bump 220. Thus, while attaching the semiconductor chip 110 to the package substrate, stresses applied to a metal wiring in the semiconductor chip 110 can be reduced.

In exemplary embodiments, a shape of the capping layer 230 changes based on a shape of the pillar bump 220. For example, when the pillar bump 220 has a cylindrical shape, the capping layer 230 has an annular shape that surrounds the cylindrical pillar bump 220.

According to an exemplary embodiment, the capping layer 230 supports the pillar bump 220 to prevent a short between tall pillar bumps 220. If the capping layer 230 melts before the pillar bump 220 while attaching the semiconductor chip 110 to the package substrate via the pillar bump 220, the melted capping layer 230 will not support the pillar bump 220. Thus, the capping layer 230 includes a metal having a higher melting point than the pillar bump 220. For example, the melting point of the capping layer 230 is not less than about 500° C. Examples of a capping layer metal include Cu, Ni, Ag, Au, Pt, etc.

According to an exemplary embodiment, the capping layer 230 has a thickness Tc measured from the outer surface of the pillar bump 220. In exemplary embodiments, the thickness Tc of the capping layer 230 is uniform. The thickness Tc of the capping layer 230 is about 0.04 times to about 0.5 times of the width Tb of the pillar bump 220. If the thickness Tc of the capping layer 230 is less than about 0.04 times the width Tb of the pillar bump 220, a force of the capping layer 230 that supports the pillar bump 220 is weakened. In contrast, because a gap between the pillar bumps 220 is restricted to within a specific distance, a maximum thickness Tc of the capping layer 230 is no greater than about 0.5 times the width Tb of the pillar bump 220.

According to an exemplary embodiment, if the capping layer 230 has a height substantially the same as the height Hb of the pillar bump 220, the outer surface of the pillar bump 220 is entirely covered by the capping layer 230 so that only the upper surface of the pillar bump 220 is exposed. In this case, a contact area between the pillar bump 220 and the pad of the package substrate is reduced, weakening an adhesion force between the semiconductor chip 110 and the package substrate.

Therefore, according to an exemplary embodiment, the capping layer 230 has a height Hc less than the height Hb of the pillar bump 220. An upper portion of the outer side surface as well as the upper surface of the pillar bump 220 are exposed by the capping layer 230 with height Hc. Thus, the contact area between the pillar bump 220 and the pad of the package substrate is sufficiently large to reinforce the adhesion force between the semiconductor chip and the package substrate.

According to an exemplary embodiment, the height Hc of the capping layer 230 measured from the upper surface of the UBM layer 210 is about 0.5 times to 0.7 times the height Hb of the pillar bump 220. If the height Hc of the capping layer 230 is greater about 0.7 times the height HI-b of the pillar bump 220, an area of the pillar bump 220 exposed by the capping layer 230 is reduced, which weakens the adhesion force between the semiconductor chip 110 and the package substrate. In contrast, if the height Hc of the capping layer 230 is less than about 0.5 times the height Hb of the pillar bump 220, the supporting force of the capping layer 230 is weakened. In particular, the height Hc of the capping layer 230 can be accurately controlled by a method of forming the bump structure according to exemplary embodiments that is disclosed below.

Semiconductor Package

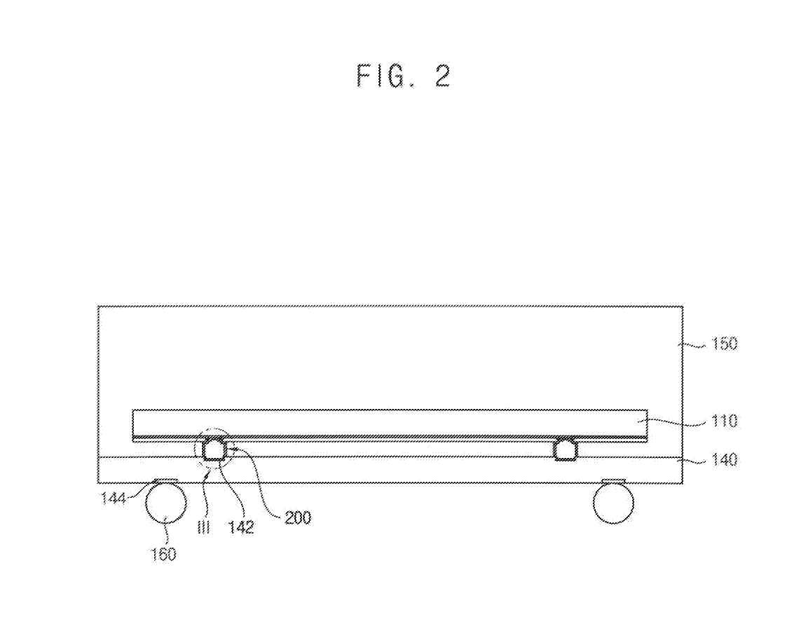

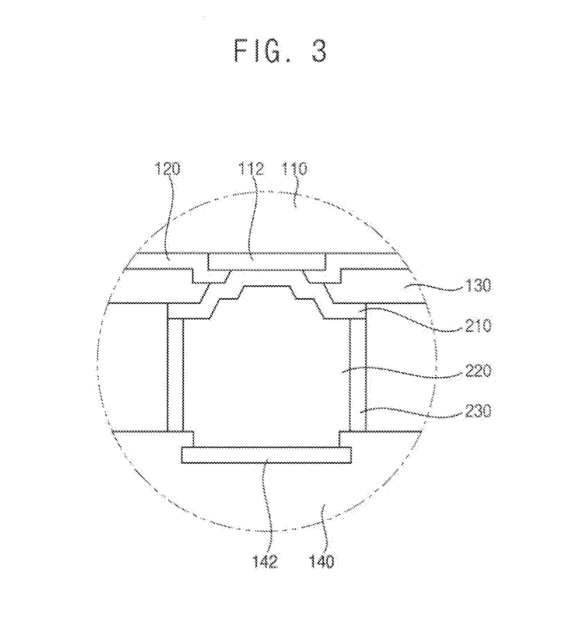

FIG. 2 is a cross-sectional view of a semiconductor package that includes a bump structure in FIG. 1 in accordance with exemplary embodiments, and FIG. 3 is an enlarged cross-sectional view of a portion III in FIG. 2.

Referring to FIGS. 2 and 3, a semiconductor package according to an exemplary embodiment includes a package substrate 140, a semiconductor chip 110, a bump structure 200, a molding member 150 and external terminals 160.

According to an exemplary embodiment, the package substrate 140 is an insulating substrate that includes an upper pad 142 and a lower pad 144. The upper pad 142 is disposed on an upper surface of the insulating substrate. The lower pad 144 is disposed on a lower surface of the insulating substrate. The upper pad 142 and the lower pad 144 are electrically connected with each other through a conductive line in the insulating substrate.

According to an exemplary embodiment, the semiconductor chip 110 is disposed over the package substrate 140. The pad 112 is disposed on a lower surface of the semiconductor chip 110. The bump structure 200 is formed on the pad 112 of the semiconductor chip 110. The bump structure 200 electrically connects with the upper pad 142 of the package substrate 140. That is, a structure formed by reversing the semiconductor chip 110 and the bump structure 200 in FIG. 1 can be attached to the package substrate 140.

According to an exemplary embodiment, the bump structure 200 includes elements substantially the same as those of a bump structure in FIG. 1. Thus, the same reference numerals may refer to the same elements and any further illustrations with respect to the same elements are omitted herein for brevity. Further, because the bump structure 200 in FIG. 2 is formed by reversing the bump structure 200 in FIG. 1, a lower portion of the pillar bump 220 oriented toward the upper pad 142 of the package substrate 140 is exposed through the capping layer 230.

Thus, according to an exemplary embodiment, a lower portion of the outer side surface as well as the lower surface of the pillar bump 220 is exposed to ensure a sufficiently large contact area between the pillar bump 220 and the upper pad 142. Therefore, the adhesion force between the package substrate 140 and the semiconductor chip 110 is reinforced. In particular, because the pillar bump 220 includes only solder, the pillar bump 220 can be attached to the upper pad 142 without forming solder on the upper pad 142 of the package substrate 140. That is, the pillar bump 220 can be attached to the upper pad 142 without performing a reflow process.

According to an exemplary embodiment, the capping layer 230 is disposed around the pillar bump 220 and extends vertically upward from the UBM layer 210 in a direction substantially perpendicular to a plane of the pad 112. Thus, stresses applied to the metal wiring in the semiconductor chip 110 that are generated by attaching the semiconductor chip 110 to the package substrate 140, are reduced.

According to an exemplary embodiment, the molding member 150 is formed on the upper surface of the package substrate 140 that covers the semiconductor chip 110. The molding member 150 protects the semiconductor chip 110 from the external environment. The molding member 150 includes an epoxy molding compound (EMC).

According to an exemplary embodiment, the external terminals 160 are mounted on the lower pad 144 of the package substrate 140. The external terminals 160 include solder balls.

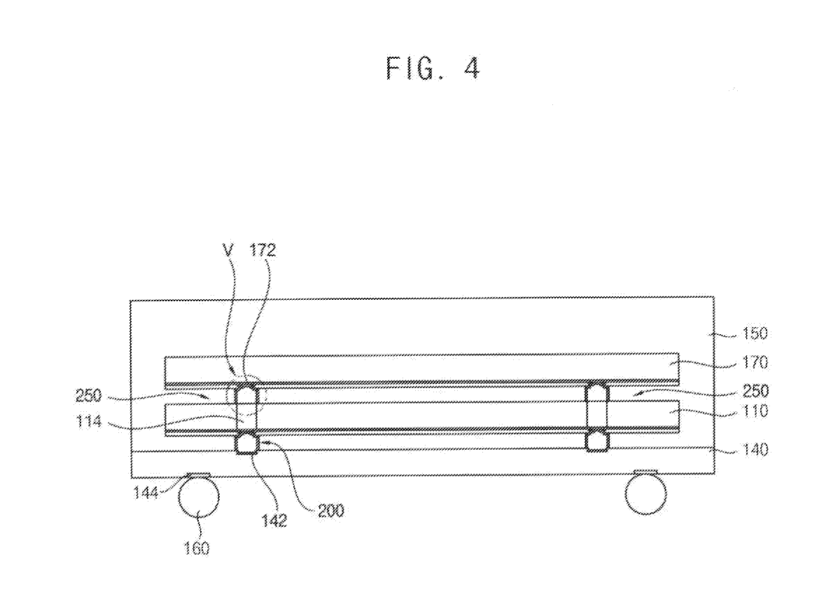

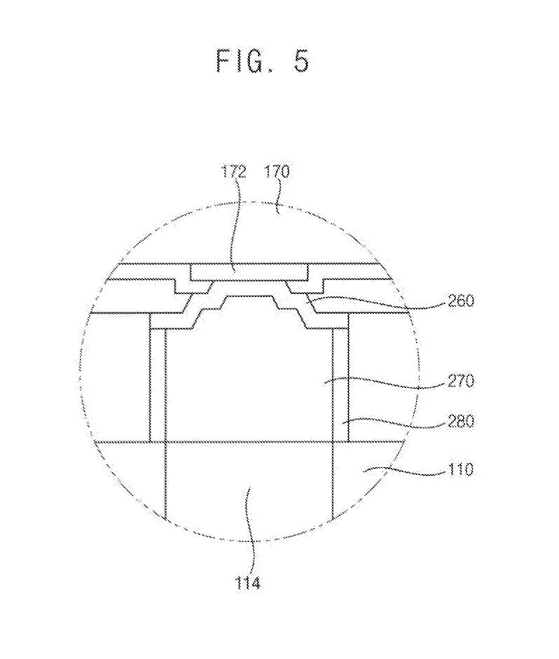

FIG. 4 is a cross-sectional view of a semiconductor package that includes a bump structure in FIG. 1 in accordance with exemplary embodiments, and FIG. 5 is an enlarged cross-sectional view of a portion IV in FIG. 4.

According to an exemplary embodiment, a semiconductor package of an exemplary embodiment of FIG. 4 includes elements substantially the same as those of a semiconductor package in FIG. 2 except for further including a second semiconductor chip and a second bump structure. Thus, the same reference numerals may refer to the same elements and any further descriptions of the same elements is omitted herein for brevity.

Referring to FIGS. 4 and 5, according to an exemplary embodiment, a semiconductor package corresponds to a multi-chi package that includes at least stacked two semiconductor chips.

Therefore, according to an exemplary embodiment, a connection post 114 is vertically formed in the semiconductor chip 110. The connection post 114 includes a lower end that electrically connects with the pad 112 of the semiconductor chip 110. The connection post 114 includes an upper end exposed through the upper surface of the semiconductor chip 110.

According to an exemplary embodiment, a second semiconductor chip 170 is disposed over the semiconductor chip 110. A second pad 172 is disposed on a lower surface of the second semiconductor chip 170.

According to an exemplary embodiment, a second bump structure 250 electrically connects the second pad 172 of the second semiconductor chip 170 with the upper end of the connection post 114. The second bump structure 250 includes a second UBM layer 260, a second pillar bump 270 and a second capping layer 280. The second UBM layer 260, the second pillar bump 270 and the second capping layer 280 of the second bump structure 250 have shapes and functions substantially the same as those of the UBM layer 210, the pillar bump 220 and the capping layer 230 of the bump structure 200 in FIG. 2. Thus, any further descriptions of the second bump structure 250 are omitted herein for brevity.

According to an exemplary embodiment, the molding member 150 is formed on the upper surface of the package substrate 140 that covers the semiconductor chip 110 and the second semiconductor chip 170.

In exemplary embodiments, the semiconductor package includes two stacked semiconductor chips. Alternatively, the semiconductor package includes at least three stacked three semiconductor chips that are electrically connected with each other via the bump structure 200 in FIG. 1.

Method of Forming a Bump Structure

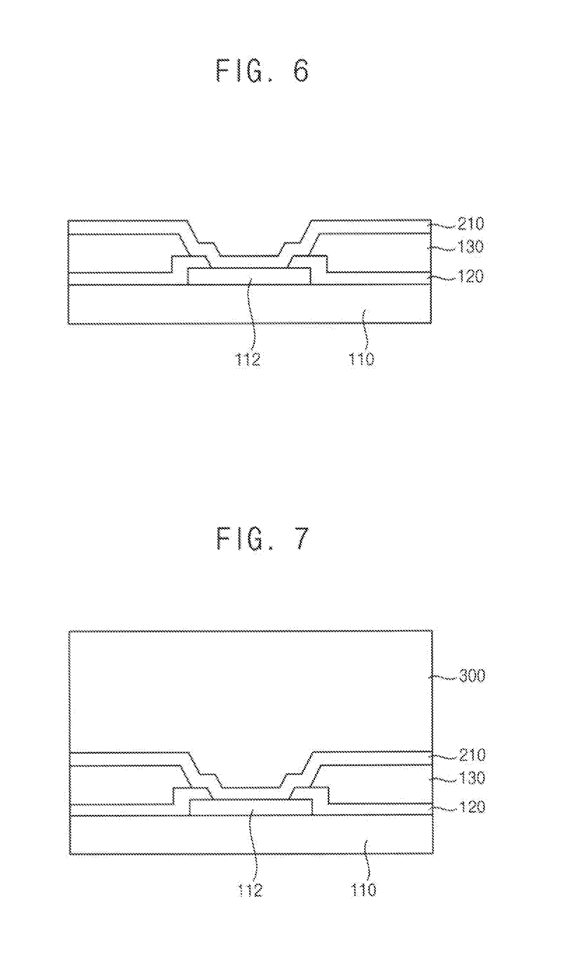

FIGS. 6 to 16 are cross-sectional views that illustrate a method of forming the bump structure in FIG. 1.

Referring to FIG. 6, according to an exemplary embodiment, the pad 112 is formed on the upper surface of the semiconductor chip 110. The passivation layer 120 is formed on the upper surface of the semiconductor chip 110 to expose the pad 112. The insulating pattern 130 is formed on the upper surface of the passivation layer 120 to expose the pad 112. The UBM layer 210 is formed on the insulating pattern 130 and the pad 112.

Referring to FIG. 7, according to an exemplary embodiment, a first photoresist film 300 is formed on the upper surface of the UBM layer 210. The first photoresist film 300 has a height that defines a height of the pillar bump 220.

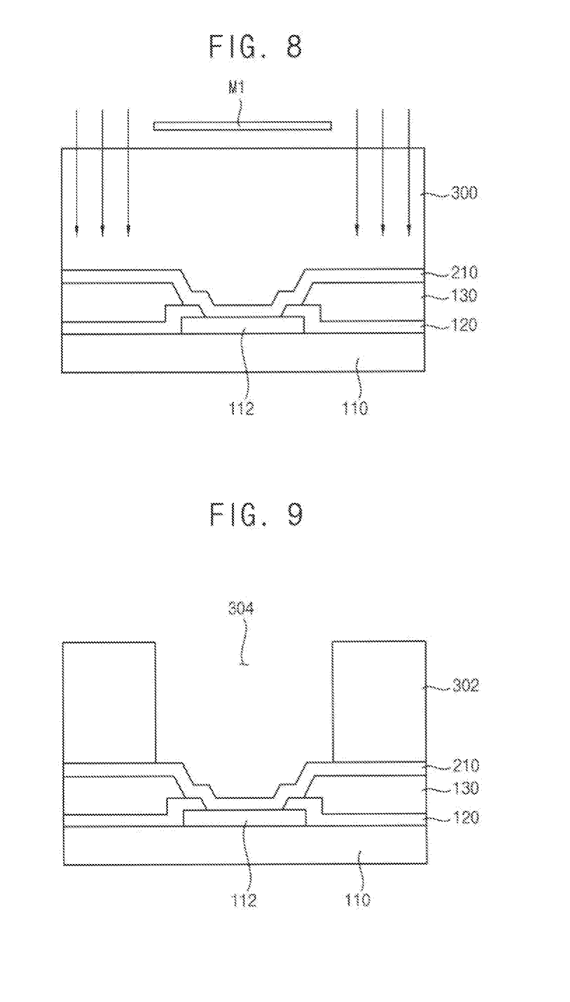

Referring to FIG. 8, according to an exemplary embodiment, a first photo mask M1 is positioned over the pad 112. An exposure process is performed on the first photoresist film 300 using the first photo mask M1. Because the first photo mask M1 is placed over the pad 112, light is blocked from being irradiated onto a portion of the first photoresist film 300 under the photo mask M1 and over the pad 112.

Referring to FIG. 9, according to an exemplary embodiment, the first photomask M1 is removed. A developing process is performed on the exposed first photoresist film 300 to form a first photoresist pattern 302. Only the portion of the first photoresist film 300 over the pad 112 is removed by the developing process. Thus, the first photoresist pattern 302 has a first opening 304 that exposes a portion of the UBM layer 210 over the pad 112. The first opening 304 has a width that defines a width of the pillar bump 220.

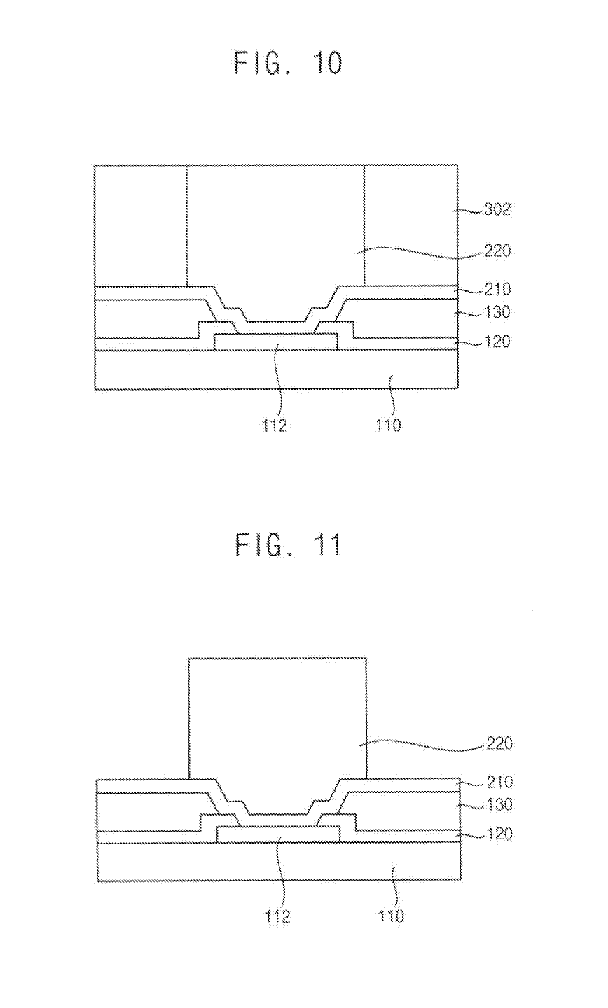

Referring to FIG. 10, according to an exemplary embodiment, the pillar bump 220 is formed in the first opening 304 of the first photoresist pattern 302. The pillar bump 220 is formed by an electroplating process on the UBM layer 210 exposed through the first opening 304.

According to an exemplary embodiment, the pillar bump 220 has a height Hb measured from the upper surface of the UBM layer 210 and a width Tb. The pillar bump 220 includes tin or a tin alloy. Examples of a tin alloy include Sn—Bi, Sn—Ag, Sn—Cu, Sn—Ag—Cu, etc.

Referring to FIG. 11, according to an exemplary embodiment, the first photoresist pattern 302 is removed by an ashing process or a stripping process.

Referring to FIG. 12, according to an exemplary embodiment, a second photoresist film 310 is formed on the upper surface of the UBM layer 210. The second photoresist film 310 is not formed on the upper surface of the pillar bump 220. Thus, the second photoresist film 310 may have a shape that surrounds the outer side surface of the pillar bump 220. The second photoresist film 310 makes contact with the outer side surface of the pillar bump 220.

In exemplary embodiments, the second photoresist film 310 has an upper surface lower than the upper surface of the pillar bump 220. That is, a height of the second photoresist film 310, as measured from the upper surface of the UBM layer 210, is less than the height Hb of the pillar bump 220. Therefore, an upper portion of the outer side surface of the pillar bump 220 is exposed through the second photoresist film 310. A height of the capping layer 230 is determined by the height of the second photoresist film 310. The height of the second photoresist film 310 is about 0.5 times to about 0.7 times the height Hb of the pillar bump 220.

Alternatively, according to an exemplary embodiment, the second photoresist film 310 has an upper surface substantially coplanar with the upper surface of the pillar bump 220. That is, a height of the second photoresist film 310 measured from the upper surface of the UBM layer 210 is substantially the same as the height Hb of the pillar bump 220. In this case, the upper portion of the outer side surface of the pillar bump 220 is covered by the second photoresist film 310.

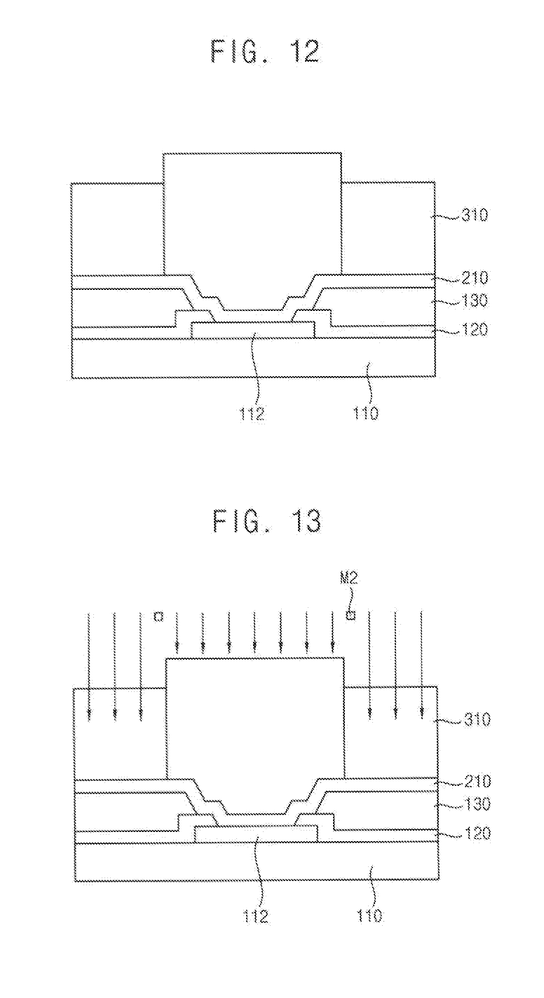

Referring to FIG. 13, according to an exemplary embodiment, a second photo mask M2 is disposed over the second photoresist film 310. The second photo mask M2 has a shape that blocks a portion of the second photoresist film 310 that makes contact with the outer side surface of the pillar bump 220. For example, if the pillar bump 220 has a circular cross-sectional shape, the second photo mask M2 has an annular shape whose diameter is slightly greater than that of the pillar bump 220.

According to an exemplary embodiment, an exposure process is performed on the second photoresist film 310 using the second photo mask M2. Because the second photo mask M2 is disposed over a portion of the second photoresist film 310 that makes contact with the outer side surface of the pillar bump 220, light is blocked from irradiating the portion of the second photoresist film 310 that makes contact with the outer side surface of the pillar bump 220.

Referring to FIG. 14, according to an exemplary embodiment, the second photo mask M2 is removed. A developing process is performed on the exposed second photoresist film 310 to form a second photoresist pattern 312. The portion of the second photoresist film 310 that makes contact with the outer side surface of the pillar bump 220 to which light was not irradiated is removed by the developing process. Thus, the second photoresist pattern 312 has a second opening 314 that exposes the outer side surface of the pillar bump 220 and a portion of the UBM layer 210 connected to a lower end of the exposed outer side surface of the pillar bump 220. A thickness of the capping layer 230 is determined by a thickness of the second opening 314 measured from the outer side surface of the pillar bump 220. Further, because the height of the second photoresist film 310 is about 0.5 times to about 0.7 times the height Hb of the pillar bump 220, the second opening 314 has a height of about 0.5 times to about 0.7 times the height Hb of the pillar bump 220.

Alternatively, according to an exemplary embodiment, if the height of the second photoresist film 310 is substantially the same as the height Hb of the pillar bump 220, the second opening 314 has a height substantially the same as the height Hb of the pillar bump 220.

In exemplary embodiments, the thickness of the second opening 314 is uniform. Alternatively, in other exemplary embodiments, the second opening 314 has a thickness that gradually increases from a lower end to an upper end of the second opening 314. Further, in other exemplary embodiments, the second opening 314 has a stepped structure having at least two thicknesses.

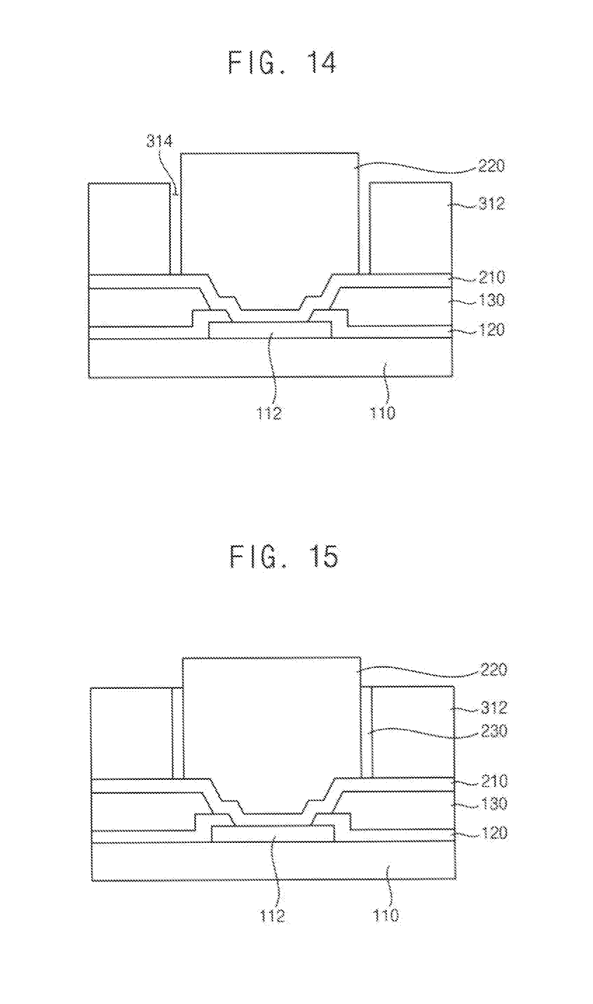

Referring to FIG. 15, according to an exemplary embodiment, the capping layer 230 is formed in the second opening 314 of the second photoresist pattern 310. The second opening 314 of the second photoresist pattern 310 is completely filled with the capping layer 230 so that the capping layer 230 has a shape substantially the same as that of the second opening 314. Because the height of the second opening 314 is less than the height Hb of the pillar bump 220, the capping layer 230 has a height less than the height Hb of the pillar bump 220. Thus, an upper portion of the outer side surface of the pillar bump 220 is exposed through the capping layer 230.

In exemplary embodiments, the capping layer 230 is formed by an electroplating process performed on the UBM layer 210 exposed through the second opening 314. The height Hc and the thickness Tc of the capping layer 230 is determined by controlling the electroplating process by which the capping layer 230 is vertically formed to the height of the second opening 314. Thus, the height Hc of the capping layer 230 is about 0.5 times to about 0.7 times the height Hb of the pillar bump 220. Further, the thickness Tc of the capping layer 230 is about 0.04 times to about 0.5 times the width Tb of the pillar bump 220.

According to an exemplary embodiment, the capping layer 230 includes a metal having a melting point higher than that of the pillar bump 220. For example, the melting point of the capping layer 230 is no less than about 500° C. Examples of a metal include Cu, Ni, Ag, Au, Pt, etc.

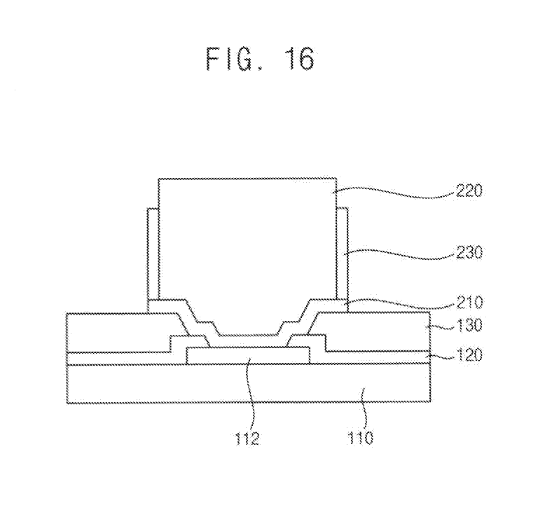

Referring to FIG. 16, according to an exemplary embodiment, the second photoresist pattern 312 is removed by an ashing process or a stripping process.

According to an exemplary embodiment, a portion of the UBM layer 210 that horizontally protrudes from the outer side surface of the capping layer 230 is removed to complete the bump structure 200 in FIG. 1. The bump structure 200 can be attached to the package substrate without performing a reflow process.

According to exemplary embodiments, a capping layer having a height of about 0.5 times to 0.7 times the height of the pillar bump can suppress stress applied to metal wiring in the semiconductor chip and to maintain an adhesion force between the pillar bump and the package substrate. In particular, the capping layer is formed in an opening of a photoresist pattern around a pillar bump by a plating process so that the capping layer has the height within the above-mentioned range.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present invention. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A bump structure of a semiconductor package, comprising:
an under bump metal (UBM) layer disposed on a pad of a semiconductor chip;
a pillar bump disposed on the UBM layer; and
a capping layer disposed on the UMB layer, wherein the capping layer surrounds an outer side surface of the pillar bump and has a height of about 0.5 times to about 0.7 times a height of the pillar bump as measured from the UBM layer wherein an upper portion of the outer side surface of the pillar bump is exposed.

2. The bump structure of the semiconductor package of claim 1, wherein the capping layer makes contact with the outer side surface of the pillar bump.

3. The bump structure of the semiconductor package of claim 1, wherein the capping layer extends vertically upward from an edge of the UBM layer in a direction substantially perpendicular to a plane of the pad.

4. The bump structure of the semiconductor package of claim 1, wherein the capping layer has a thickness of about 0.04 times to about 0.5 times a width of the pillar bump.

5. A semiconductor package comprising:
a package substrate;
a first semiconductor chip disposed over the package substrate; and
a first bump structure that includes a first under bump metal (UBM) layer disposed on a pad of the first semiconductor chip, a first pillar bump disposed on the first UBM layer and that is electrically connected with the package substrate, and a first capping layer disposed on an edge of the first UBM layer that surrounds the first pillar bump, the first capping layer having a height of about 0.5 times to about 0.7 times a height of the first pillar bump as measured from the first UBM layer wherein an upper portion of an outer side surface of the first pillar bump oriented toward the package substrate is exposed.

6. The semiconductor package of claim 5, wherein the first semiconductor chip comprises a connection post in the first semiconductor chip.

7. The semiconductor package of claim 6, further comprising:
a second semiconductor chip disposed over the first semiconductor chip; and
a second bump structure that includes a second UBM layer disposed on a second pad of the second semiconductor chip, a second pillar bump disposed on the second UBM layer and that is electrically connected with the connection post, and a second capping layer disposed on an edge of the second UBM layer that surrounds the second pillar bump, the second capping layer having a height of about 0.5 times to about 0.7 times a height of the second pillar bump as measured from the second UBM layer wherein an upper portion of an outer side surface of the second pillar bump oriented toward the connection post is exposed.

8. The semiconductor package of claim 5, further comprising:
a molding member disposed on an upper surface of the package substrate that covers the first semiconductor chip; and
an external terminal mounted on a lower surface of the package substrate.

9. A method of forming a bump structure of a semiconductor package, the method comprising:
forming a under bump metal (UBM) layer on a pad of a semiconductor chip;
forming a pillar bump on the UBM layer;
forming a photoresist pattern on the UBM layer, the photoresist pattern having an opening that exposes an outer side surface of the pillar bump and a portion of the UBM layer; and
forming a capping layer in the opening of the photoresist pattern.

10. The method of claim 9, wherein forming the photoresist pattern on the UBM layer comprises:
forming a photoresist film on the UBM layer; and
exposing the photoresist film using a photo mask disposed over a portion of the photoresist film that makes contact with the outer side surface of the pillar bump to form the opening.

11. The method of claim 10, wherein photoresist film has a height lower than a height of the pillar bump.

12. The method of claim 11, wherein the height of the photoresist film is about 0.5 times to about 0.7 times the height of the pillar bump measured from the UBM layer.

13. The method of claim 10, wherein the opening has a thickness of about 0.04 times to about 0.5 times a width of the pillar bump.

14. The method of claim 9, wherein forming the capping layer comprises performing a plating process on the UBM layer.

15. The method of claim 9, wherein the capping layer comprises a metal having a melting point higher than that of the pillar bump.

16. The method of claim 15, wherein the melting point of the capping layer is no less than about 500° C.

17. The method of claim 15, wherein the pillar bump comprises tin or a tin alloy.

18. The method of claim 15, wherein the capping layer comprises Cu, Ni, Ag, Au or Pt.

19. The method of claim 9, wherein forming the pillar bump comprises:
forming a photoresist film on the UBM layer;
exposing the photoresist film with a photo mask to form a photoresist pattern having an opening, wherein the opening exposes a portion of the UBM layer over the pad; and
forming the pillar bump in the opening of the photoresist pattern.

20. The method of claim 19, wherein forming the pillar bump in the opening comprises performing a plating process on the UBM layer.
